(19) United States
(12) Patent Application Publication
(10) Pub. No.: US 2014/0265793 A1
(43) Pub. Date: Sep. 18, 2014

(54) BIDIRECTIONAL SLIDE RAIL

(71) Applicant: Silicon Graphics International Corp., Fremont, CA (US)

(72) Inventors: Lance MacKimmie Evans, Boulder, CO (US); Jim Joseph Brewer, Longmont, CO (US); Kevin Lee Van Pelt, Longmont, CO (US)

(73) Assignee: Silicon Graphics International Corp., Fremont, CA (US)

(21) Appl. No.: 14/082,090

(22) Filed: Nov. 15, 2013

Related U.S. Application Data
(60) Provisional application No. 61/794,690, filed on Mar. 15, 2013.

(51) Int. Cl. H05K 7/18; H05K 5/02

(52) U.S. Cl. CPC H05K 7/183; H05K 5/0217
USPC 312/334.44; 312/223.2

(57) ABSTRACT

Computing components housed in a chassis interacts with a bidirectional slide rail system. The bidirectional slide rail system allows the computing components to be maneuvered in two directions—it may be pulled out about halfway to the front of the cabinet and/or pulled out halfway out of the back of the cabinet. This allows for easier access to components of the storage server and allows such components to be serviced from the top of the chassis.

### CROSS-REFERENCE TO RELATED APPLICATIONS

This application claims the priority benefit of U.S. Provisional Application Ser. No. 61/794,690, titled “Bidirectional Slide Rail,” filed Mar. 15, 2013, the disclosure of which is incorporated herein by reference.

### BACKGROUND

1. Field of the Invention

The present invention relates to a slide rail system. More particularly, the present invention relates to a bidirectional slide rail system for use with a computer equipment rack to enable top down servicing of computer equipment from the front or rear of the rack.

2. Description of the Related Art

A key aspect of almost any business is the smooth and reliable operation of its data center and Information Technology (IT) equipment. A data center typically includes multiple enclosures or cabinets for housing equipment modules that include computer server equipment in a chassis, such as a tray or blade. A single cabinet commonly stores several chassis and multiple cabinets are often arranged in long rows separated by a service aisle. Data center employees may enter the service aisle to manage cables, fix connection issues, or perform routine maintenance or other tasks associated with the equipment.

As the demand for data storage has increased, storage servers stored in data center cabinets have become more densely packed. As a result, easy access to various components within a storage server is hindered thus posing a challenge during servicing. Another challenge is the weight of the storage chassis and overall cabinet. A chassis housing a storage server, for example, can be quite heavy (i.e., some are over 220 pounds). This poses several problems. When a chassis is nearly or fully extended into the service aisle, the entire cabinet may become unstable. Due to the increased weight of the chassis, the cabinet may tip over while servicing the densely packed storage server chassis and result in damage to the equipment within the cabinet. More importantly, this tipping hazard may seriously endanger data center personnel who may be in the aisle servicing the equipment. Moreover, safety organizations (e.g., Underwriters Laboratories, Conformité Européene or Electronic Industries Alliance (EIA)) have set forth safety requirements related to the characteristics and durability of extendable cabinet rails and require the testing of such rails in a fully extended position with additional weight applied to the cabinet at its center of gravity.

There is a need in the art for a solution that improves access to equipment modules such as storage media within an enclosure and reduces hazards to data center personnel servicing the same.

### BRIEF DESCRIPTION OF DRAWINGS

FIG. 1A illustrates a slide rail system with a storage server in the front position of an enclosure or cabinet.

FIG. 1B illustrates a slide rail system with a storage system 110 in the rear position of a cabinet.

FIG. 2 illustrates a bidirectional slide rail system.

FIG. 3 illustrates a perspective view of an exemplary inner rail.

FIG. 4 illustrates a sliding inner rail.

FIG. 5 illustrates a perspective view of an exemplary outer rail.

FIG. 6 illustrates a sliding outer rail.

### DETAILED DESCRIPTION

The slide rail system of the presently claimed invention provides for improved access to computer equipment, such as storage media, on a chassis, drawer, or tray. In a densely packed storage server of the prior art, components are tightly packed within the chassis and are thus difficult to access and/or service. To adequately service a storage server, the entire chassis must fully slide out the front of the cabinet or be removed out of the cabinet entirely. This requires that the service aisle area in front of the cabinet to be equal or greater than the depth of the computer equipment, which can be over 36 inches deep.

In one embodiment, improved access to a storage server is achieved. Although a storage server is discussed in this embodiment, it is exemplary and not limiting; any rack-mount equipment or electric module, for example, may fall under the scope of the invention. A storage server housed in a chassis interacts with a bidirectional slide rail system, that are both mounted in a cabinet. The bidirectional slide rail system of the presently claimed invention allows the storage server chassis to be maneuvered in two directions—it may be pulled out about halfway to the front of the cabinet and/or pulled about halfway out of the back of the cabinet. This allows for easier access to components of the storage server and allows such components to be serviced from the top of the chassis. Also, since the chassis can only move about halfway in the front or rear of the cabinet, less of the service aisle is required during service. As such, this feature provides more workspace in an already constrained service aisle.

FIG. 1A illustrates a slide rail system 100 with storage server 110 in the front position of an enclosure or cabinet. A cabinet may be a standard 19″ rack and may contain one or more slide rail systems with associated equipment or media. Storage server 110 is in contact with a first slide rail system 120A and second slide rail system 120B of slide rail system 100. FIG. 1B illustrates a slide rail system 100 with storage server 110 in the rear position of a cabinet.

FIG. 2 illustrates a bidirectional slide rail system. The rail system of the presently claim invention may include an inner rail and an outer rail. In one embodiment, the outer rail length may be adjustable from 28-36 inches. The outer rail as illustrated is “C-shaped” but may be implemented in other shapes and sizes. The outer rail may be a fixed channel that is attached, fastened, connected, or mounted by any means known in the art to the rack or cabinet. The inner rail is a slide rail that is attached or fixed by any means known in the art to the storage server or other equipment. The inner rail contacts, moves, or slides parallel against/to the outer rail. The inner rail may slide bidirectionally—forwardly towards the front of the cabinet or enclosure or rearwardly—within the fixed channel of the outer rail.

In one embodiment, the chassis may be able to extend in the front or rear positions. In one embodiment, the chassis may extend up to 18-20 inches in the front or rear positions. Since the movement of the chassis is limited (that is, the entire chassis does not extend fully in the forward or rearward positions), less cabling or electrical connection material is required. Cords or cables, for example, are shorter (e.g., one meter or less) than those typically used in chassis systems and do not have to be as long as cords or cables used in the prior art. Furthermore, since the chassis may be maneuvered bidirectionally, the slide rail system of the presently claimed invention may be used with one or more rack arms that allow for cable management and the forward and rearward movement of the chassis and the components housed within it. For purposes of describing the present invention herein, the term “rearwardly” shall refer to a direction away from the front of the cabinet or enclosure. In another embodiment, the slide rail includes rollers.

In the bidirectional slide rail system of FIG. 2, the inner rail operates to move the chassis against the outer rail. The rails and extension stops may be configured such that, when the chassis is fully extended along the rails, an outer surface of the chassis is not more than 20 inches from an outer surface of the computer enclosure.

While FIG. 2 shows a simplified illustration of the slide rail system, the presently claimed invention may include multiple pieces of hardware fastened or fixed together using known methods in the art. The slide rail system may include mounting for square hole, round hole, or threaded hole racks and utilize any suitable mechanical parts known in the art such as fasteners, rivets, springs, rollers, latches, hooks, ribs, tabs, etc. The slide rail system may be molded or created from any suitable material. In one embodiment, the slide rail system is made from sheet metal.

As shown in FIG. 2, the slide rail system includes one or more extension stops that may be spring loaded. In other embodiments, an extension stop may be a solid stop. The extension stop prevents the slide rail from extending past a designated position (i.e., the slide rail would stop at the location of an extension stop) in the forward or rearward direction. At full extension in the forward or rearward position, the extension stop further allows the release or removal of the slide rail and attached equipment from the cabinet or rack.

FIG. 3 illustrates a perspective view of an exemplary inner rail. Inner rail 310 includes extension stops 320, 330 and 340, and 350, and inner rail handles 360 and 370. FIG. 3 illustrates the extension stops and rail handles 370 as separate from the rail 310 though the parts are attached to the rail at one end of the stop when in use on a chassis within a rack.

The extension stops may be spring activated so that they extend away from the side of the inner rail towards the outer rail. The extension stops may engage a fixed channel in the outer rail such that the end of the stop not attached to the inner rail goes through the channel when the unattached end aligns with the channel. Once in the channel, the end of the stop extension stop attached to the inner rail will not pass through the channel, thereby preventing the chassis to extend any further in a particular direction.

As a result of the dual extension stop design, a rack may include multiple chassis wherein each chassis is attached to the rack using a bidirectional rail. The rail may extend each chassis in a frontward direction from the front of the rack and a rearward direction from the rear of the rack. The bidirectional rail may allow for extending a chassis forward so that the front end of the chassis extends past the front of the rack and extending the chassis backward so that the back end of the chassis extends past the back of the rack. The inner rail includes one or more extension stops to prevent the chassis from being extended past a designated distance from the rack. The distance may correspond to half the length of the rack, more than half the rack, or some other distance.

FIG. 4 illustrates a side view of a sliding inner rail. The inner rail 410 includes extension stop 420, 430, 440 and 450. Extension stops 420 and 430 are attached to the inner rail at portions 460 and 470. The extension stops may include bent portions of material, such as sheet metal, that may engage an extension blocks. For example, extension stops may extend through apertures in tap stops or the tip of an extension stop may engage the flat surface of a tab stop.

The, extension stops 430 and 450 are positioned higher vertically on the inner rail than extension stops 420 and 440. The vertically higher extension stops are positioned to engage a first fixed channel in the outer rail. While the vertically lower extension stops are positioned to engage a second fixed channel in the outer rail.

FIG. 5 illustrates a perspective view of an exemplary outer rail. Outer rail 510 may include fixed channels 520 and 530, and attachment mechanism 540. Fixed channels 520 and 530 may be engaged by extension stops coupled to an inner rail. When the extension stops engage the outer rail fixed channels, the extension of a rack in a particular direction is prevented.

Mechanism 540 may be attached to outer rail 510 to attach the rail assembly (an outer rail and inner rail) and corresponding chassis to a rack. The mechanism may be attached to the rack intended to hold the chassis. Attachment mechanism 540 may also be attached to outer rail 510 using any of numerous attachment apertures and corresponding screws, bolts, or other attachment parts.

FIG. 6 illustrates a sliding outer rail. Outer rail 510 of FIG. 6 includes fixed channels 530 and 520. Fixed channel 520 is positioned on outer rail 510 in a higher vertical position than fixed channel 530. As such, fixed channel 520 may be positioned to engage the higher vertically positioned extension stop 430 and lower fixed channel 530 may engage lower vertically positioned engagement stop 420 (See FIG. 4).

The slide rail system may also include one or more end latches that may be spring loaded. An end latch may lock or fix the inner rail at a midpoint or other designated position unless manually released from the front or rear of the enclosure. In one embodiment, the slide rail system allows the attached server to move approximately halfway in the front or rear of the enclosure. Besides allowing easier access to server components, this feature prevents the entire cabinet from tipping over and causing damage to housed equipment and/or data center personnel near the equipment as can be caused by other designs in the prior art due to the center of gravity being significantly in front of the support feet or rollers of the cabinet. The end latches thus prevent the server from being extended beyond safe limits. Since only half of the server is permitted to slide forwardly or rearwardly, a significant portion of mass or equipment may always remain within the enclosure. As such, the center of gravity of an enclosure for use with the presently claimed invention may be located in-line with or slightly in front of the supports (e.g. caster, foot) of the of the enclosure. The tipping hazard associated with typical enclosures is thereby reduced along with the need for a hefty slide rail system since the moment arm of the weight of the extended equipment is typically half that of designs in the prior art. Such features of the presently claimed invention aid in its ability to satisfy various safety requirements of safety organizations such as Conformite Europeene (CE) or Electronic Industries Alliance (EIA)). A typical enclosure and slide rail system of the prior art may be used with one or more types of cumbersome extension plates or feet that extend out of the rack into the service aisle to keep the rack from tipping. The slide rail system of the presently claimed invention may allow one or more (or all) chassis or drawers of a rack to be extended in the forward or rearward position without causing the rack to tip over and does not require the use of temporary or permanent extension mechanisms to prevent tipping.

A slide rail system of the prior art that allows equipment to slide out fully in the front aisle commonly includes three-pieces—an inner member, an outer member, and a middle member to connect the inner and outer member. Such rail system may also include more parts or materials, such as roller or ball bearings, and be constructed from stronger or more expensive materials to be able to support a fully extended server and its increasing weight or moment. The moment of the server may increase as the server slides further out. In contrast, the presently claimed invention includes two members—an outer rail and an inner rail—rather than three members as part of a slide rail system. This feature allows for a narrower, less expensive design with fewer parts to break.

The foregoing detailed description of the technology herein has been presented for purposes of illustration and description. It is not intended to be exhaustive or to limit the technology to the precise form disclosed. Many modifications and variations are possible in light of the above teaching. The described embodiments were chosen in order to best explain the principles of the technology and its practical application to thereby enable others skilled in the art to best utilize the technology in various embodiments and with various modifications as are suited to the particular use contemplated. It is intended that the scope of the technology be defined by the claims appended hereto.

What is claimed is:

1. A slide rail system, comprising:
an outer rail fixed to the rack of a computer enclosure; and
an inner rail attached to a chassis, the chassis housing one or more computing components, wherein the inner rail operates to move the chassis against the outer rail not more than half the cabinet depth.

2. The slide rail system of claim 1, wherein inner rail operates to move the chassis against the outer rail such that an outer surface of the chassis is not more than 20 inches from an outer surface of the computer enclosure.

3. The slide rail system of claim 1, wherein the inner rail includes one or more rollers.

4. The slide rail system of claim 1, wherein the outer rail is C-shaped.

5. The slide rail system of claim 1, wherein the slide rail includes an extension stop that prevents the chassis from extending past a designated position.

6. The slide rail system of claim 1, wherein the slide rail includes an end latch for locking the inner rail in a designated position.

7. The slide rail system of claim 1, wherein the computing rack does not include a permanent or temporary extension to prevent tipping of the computing enclosure when the chassis is fully extended.

8. The slide rail system of the claim 1, wherein the computing components are serviceable from the top of the chassis.

9. A system for storing computing equipment, comprising:
a rack;
a plurality of chassis, wherein each chassis contains computer equipment; and
a bidirectional rail attaching each chassis to the rack, each bidirectional rail able to extend the chassis in an frontward direction from the front of the rack and a rearward direction from the rear of the rack.

10. The system of claim 8, wherein the bidirectional rail includes an inner rail attached to the chassis and an outer rail attached to the rack.

11. The system of claim 8, wherein the bidirectional rail extends the chassis forward so that the front end of the chassis extends past the front of the rack and extends the chassis backward so that the back end of the chassis extends past the back of the rack.

12. The system of claim 8, wherein the inner rail includes one or more extension stops to prevent the chassis from being extended past a designated distance from the rack.

13. The system of claim 11, wherein the one or more extension stops included in the rail include a first extension stop to limit extension in a first direction and a second stop to limit extension in a second direction.

14. The system of claim 13, wherein the outer rail includes a fixed channel to engage each extension stop.

15. The system of claim 8, wherein the computer equipment includes storage servers.

16. The system of claim 8, wherein the computer equipment includes servers.
